(19) United States
(12) Patent Application Publication
(10) Pub. No.: US 2016/0158964 A1
(43) Pub. Date: Jun. 9, 2016

(54) CERAMIC-ENCAPSULATED THERMOPOLYMER PATTERN OR SUPPORT WITH METALLIC PLATING

(71) Applicant: UNITED TECHNOLOGIES CORPORATION, Farmington, CT (US)

(72) Inventors: Michael S. Miarecki, Enfield, CT (US); Joseph Parkos, East Haddam, CT (US); Gary M. Lomasney, Glastonbury, CT (US); Charles R. Watson, Windsor, CT (US)

(21) Appl. No.: 14/903,903

(22) PCT Filed: Jul. 9, 2014
(86) PCT No.: PCT/US2014/045879

§ 371 Date: Jan. 8, 2016

Related U.S. Application Data
(60) Provisional application No. 61/844,108, filed on Jul. 9, 2013.

(51) Int. Cl. B28B 7/34; B28B 11/04; B28B 11/24; F01D 11/08; C04B 35/76; F01D 5/28; F01D 5/18; B28B 1/24; C04B 35/80

(52) U.S. Cl. CPC B28B 7/342; B28B 1/24; B28B 11/04; B28B 11/243; C04B 35/806; C04B 35/76; F01D 5/284; F01D 5/187; F01D 11/08; B33Y 10/00

(57) ABSTRACT

A method for fabricating a ceramic component is disclosed. The method may comprise: 1) forming a polymer template having a shape that is an inverse of a shape of the ceramic component, 2) placing the polymer template in a mold; 3) injecting the polymer template with a ceramic slurry, 4) firing the ceramic slurry at a temperature to produce a green body, and 5) sintering the green body at an elevated temperature to provide the ceramic component.

### CROSS-REFERENCE TO RELATED APPLICATIONS

This application claims priority under 35 U.S.C. §119(e) to U.S. Provisional Patent Application Ser. No. 61/844,108 filed on Jul. 9, 2013.

### FIELD OF THE DISCLOSURE

The present disclosure generally relates to ceramic-based components, and more specifically, relates to methods for fabricating ceramic-based components with complex geometrical features.

### BACKGROUND

Ceramics are desirable materials for component fabrication for gas turbine engines because they are lightweight and exhibit high thermal stability, features which could lead to substantial improvements in fuel efficiency and fuel savings. For example, the use of ceramic-based structural components as opposed to current heavier metal-based components in areas of the gas turbine engine which are exposed to hot combustion gases (i.e., turbine sections, etc.), may allow the engine to safely operate at even higher temperatures, leading to favorable increases in fuel efficiency. In this regard, the use of ceramic-based components in the turbine section such as, for example, turbine blades and/or turbine blade outer air seals (BOAS) may be highly desirable. However, due to the inherent brittleness of ceramic materials and their tendency for fracture, it is difficult to fabricate ceramic components which have complex geometrical features including internal passages and channels, cooling holes, and bolt holes by current post-manufacturing machining and drilling processes without cracking the ceramic component or inducing stress into the component which could lead to premature part failure.

Clearly, there is a need for introducing complex geometrical features into ceramic-based components by methods that reduce or eliminate the need for post-process machining and drilling that tend to induce fracture of the ceramic material.

### SUMMARY OF THE DISCLOSURE

In accordance with one aspect of the present disclosure, a method for fabricating a ceramic component is disclosed. The method may comprise forming a polymer template having a shape that is an inverse of a shape of the ceramic component, and placing the polymer template in a mold. The method may further comprise injecting the mold with a ceramic slurry, firing the ceramic slurry at a temperature to produce a green body, and sintering the green body at an elevated temperature to provide the ceramic component.

In another refinement, the polymer template may comprise voids that are devoid of polymeric material where walls are desired in the ceramic component, and filled regions that are filled with the polymeric material where open spaces are desired in the ceramic component.

In another refinement, sintering the green body at an elevated temperature may comprise volatilizing the polymer template.

In another refinement, the method may further comprise coating a surface of the ceramic component with a metal plating.

In another refinement, injecting the mold with the ceramic slurry may comprise infiltrating the voids with the ceramic slurry.

In another refinement, injecting the mold with the ceramic slurry may comprise encapsulating the polymer template in the ceramic slurry.

In another refinement, injecting the mold with the ceramic slurry may comprise infiltrating the voids with the ceramic slurry, and encapsulating the polymer template in the ceramic slurry.

In another refinement, the polymer template may be formed from a thermoplastic material selected from the group consisting of high density polypropylene and high density polyethylene.

In another refinement, forming the polymer template may comprise forming the polymer template by a method selected from the group consisting of additive manufacturing, layer-wise deposition, three-dimensional printing, injection molding, compression molding, resin transfer molding, extrusion, and blow molding.

In another refinement, injecting the mold with the ceramic slurry may comprise a method selected from the group consisting of injection, injection molding, and vacuum pressure infiltration.

In accordance with another aspect of the present disclosure, a ceramic component is disclosed. The ceramic component may be formed by a method comprising forming a polymer template having voids that are devoid of polymeric material where walls are desired in the ceramic component, and filled regions that are filled with the polymeric material where open spaces are desired in the ceramic component, and placing the polymer template in a mold. The method may further comprise injecting the mold with a ceramic slurry, firing the ceramic slurry at a temperature to produce a green body, and sintering the green body at an elevated temperature to provide the ceramic component.

In another refinement, sintering the green body at an elevated temperature may comprise volatilizing the polymer template.

In another refinement, the method may further comprise coating a surface of the ceramic component with a metal plating.

In another refinement, injecting the mold with the ceramic slurry may comprise infiltrating the voids with the ceramic slurry, and encapsulating the polymer template in the ceramic slurry.

In another refinement, the ceramic component may be a turbine blade for a gas turbine engine comprising an airfoil, a root, a leading edge, a trailing edge, and at least one internal passage extending inside of the airfoil.

In accordance with another aspect of the present disclosure, a ceramic component having an external wall and at least one internal passage extending inside of the external wall is disclosed. The ceramic component may be formed by a method comprising forming a polymer template having voids that are devoid of polymeric material where the external wall is desired in the ceramic component, and filled regions that are filled with the polymeric material where the at least one internal passage is desired in the ceramic component. The method may further comprise placing the polymer template in a mold, injecting the mold with a ceramic slurry, firing the ceramic slurry at a temperature to produce a green body, and sintering the green body at an elevated temperature to provide the ceramic component.

In another refinement, sintering the green body at an elevated temperature may comprise volatilizing the polymer template.

In another refinement, injecting the mold with the ceramic slurry may comprise infiltrating the voids with the ceramic slurry, and encapsulating the polymer template with the ceramic slurry.

In another refinement, the ceramic component may comprise a turbine blade for a gas turbine engine, the external wall may define an airfoil and a root of the airfoil, and the at least one internal passage may provide a passage for cooling air inside of the turbine blade.

In another refinement, the ceramic component may be a blade outer air seal for a gas turbine engine.

These and other aspects and features of the present disclosure will be more readily understood when read in conjunction with the accompanying drawings.

### BRIEF DESCRIPTION OF THE DRAWINGS

FIG. 1 is a front view of a ceramic component as a turbine blade, constructed in accordance with the present disclosure.

FIG. 2 is a cross-sectional view of the turbine blade of FIG. 1 taken along the line 2-2 of FIG. 1, constructed in accordance with the present disclosure.

FIG. 3 is a cross-sectional view of a polymer template for the turbine blade, constructed in accordance with the present disclosure.

FIG. 4 is a cross-sectional view similar to FIG. 3, but after infiltrating the polymer template with a ceramic material and firing to form a green body, in accordance with a method of the present disclosure.

FIG. 5 is a cross-sectional view similar to FIG. 4, but after sintering the ceramic precursor and vaporizing the polymer template to provide the turbine blade, in accordance with a method of the present disclosure.

FIG. 6 is flow chart illustrating the steps involved in fabricating the ceramic component, in accordance with a method of the present disclosure.

It should be understood that the drawings are not necessarily drawn to scale and that the disclosed embodiments are sometimes illustrated schematically and in partial views. It is to be further appreciated that the following detailed description is merely exemplary in nature and is not intended to limit the invention or the application and uses thereof. In this regard, it is to be additionally appreciated that the described embodiment is not limited to use for gas turbine engine applications. Hence, although the present disclosure is, for convenience of explanation, depicted and described as certain illustrative embodiments, it will be appreciated that it can be implemented in various other types of embodiments and in various other systems and environments.

### DETAILED DESCRIPTION

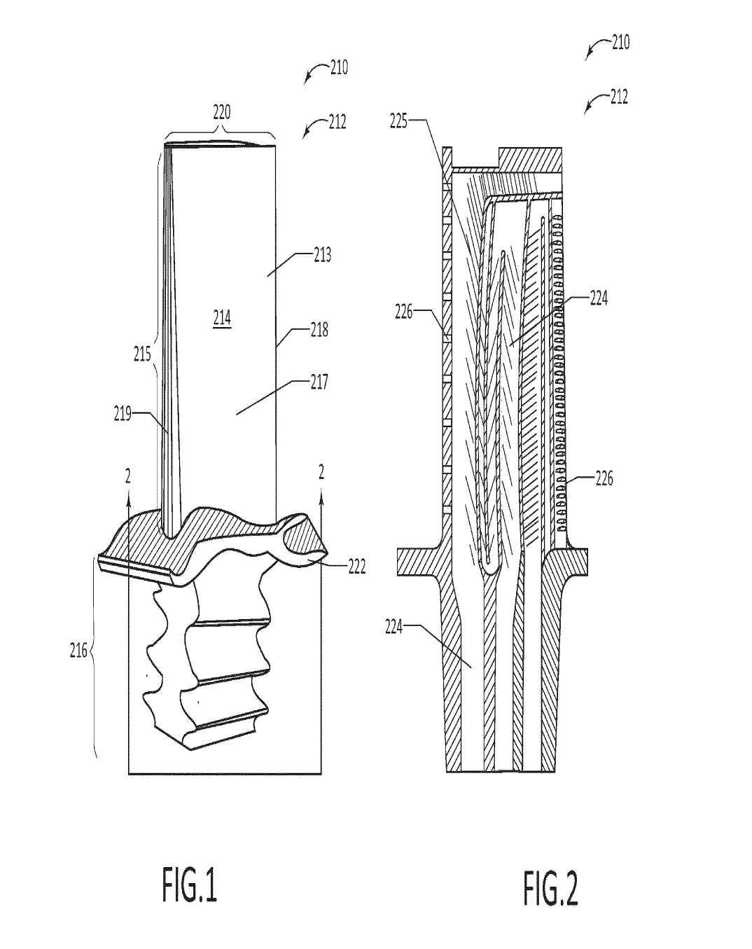

Referring now to FIGS. 1 and 2, a ceramic component 210 is depicted. The ceramic component 210 may be any structural component having high temperature capability and complex geometrical features such as, for example, internal passages, holes, pores, bolt holes, and hooks. As one non-limiting example, the ceramic component 210 may be a turbine blade 212 for use in a gas turbine engine. The turbine blade 212 may have external walls 213 which form an external surface 214 of the turbine blade's airfoil 215 and root 216, as shown. The airfoil 215 may have a pressure side 217, a convex suction side, a leading edge 218, a trailing edge 219, a tip 220, and a platform 222, as shown. The root 216 of the turbine blade 212 may extend below the airfoil 215 and attach to a turbine disk (not shown). If the ceramic component 210 is the turbine blade 212, it may have complex internal geometric features which may include one or more internal passages 224 for cooling air which enters the blade 212 from the root passages extending into the airfoil 215. The internal passages 224 may have a serpentine shape, or they may be straight passages or a combination of serpentine passages with straight passages. Furthermore, the internal passages 224 may include turbulator strips 225, internal cross-over holes, and cooling holes 226 which may be located in the airfoil tip 220, the leading edge 218, and/or the trailing edge 219. In addition, the cooling holes 226 may communicate with the internal passages 224 to provide cooling air to the external surface 214 of the turbine blade 212, as best shown in FIG. 2. As another non-limiting example, the ceramic component 210 may be a turbine blade outer air seal (BOAS) for use in a turbine section of a gas turbine engine. In any event, the ceramic component 210 may be lighter in weight than nickel-based components and may exhibit structural stability at temperatures up to about 300° F. to about 400° F. higher than current superalloy blades.

The ceramic component 210 may consist of a ceramic material such as, but not limited to, silicon carbide (SiC) and silicon nitride (Si₃N₄). Optionally, the matrix of the ceramic material may also include one or more reinforcing elements such as metallic or carbon fibers in order to structurally reinforce the ceramic component 210. As an additional optional arrangement, the ceramic component 210 may also have one or more metal plating layers (not shown) applied to one or more portions of its external surface 214, such as the blade root 216, in order to structurally reinforce selected regions of the component 210 and/or to selectively protect certain external surfaces 214 (e.g., the leading edge or the tip of the turbine blade, etc.) of the component 210 from potential localized fracture. Suitable metal plating layers may consist of any platable metal or metal alloy such as, but not limited to, nickel, cobalt, nickel-cobalt, copper, iron, boron nitride, or combinations thereof.

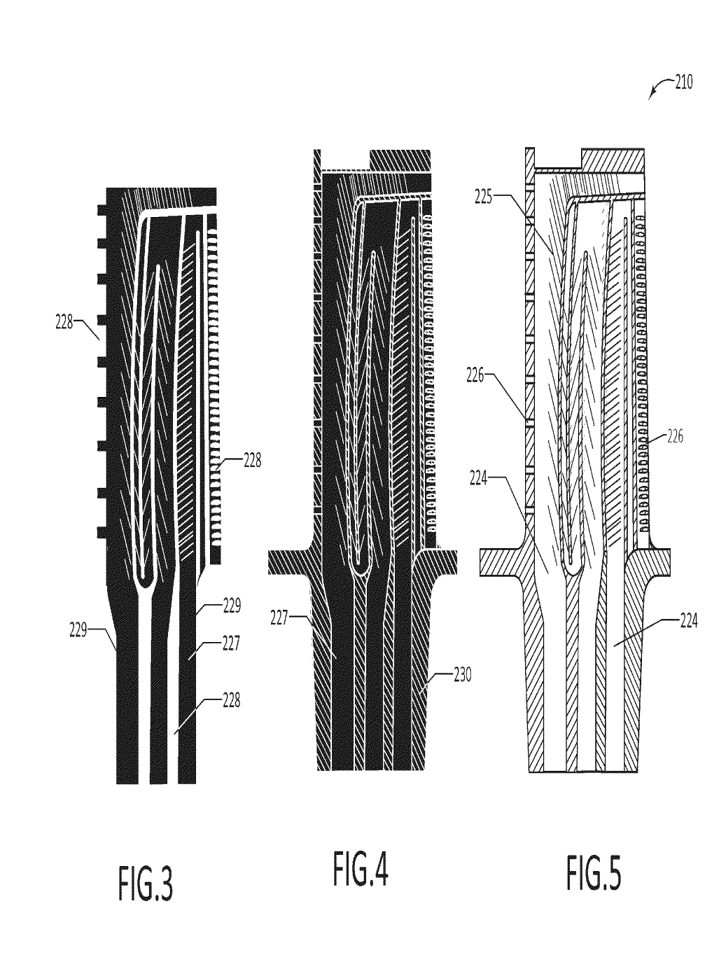

Importantly, the complex geometrical features (e.g., the internal passages 224, cross-over holes, turbulator strips 225, and the cooling holes 226) of the component 210 may be formed with a reduced or eliminated need for post-process machining, drilling, cutting, or other procedures which may otherwise cause the ceramic component 210 to crack, fracture, and/ or prematurely fail due to the inherent brittleness of ceramic materials. More specifically, the component 210 may be fabricated using a polymer template 227, as best shown in FIG. 3. In particular, the polymer template 227 may have structures which are an inverse of the desired structures of the ceramic component 210. For example, as shown in FIG. 3, if the component 210 is the turbine blade 212, the polymer template 227 may have voids 228 that are devoid of polymeric material where walls 213 are desired in the component 210, and it may have filled regions 229 filled with polymeric material where open spaces (e.g., internal passages 224, turbulator strips 225, cooling holes 226, etc.) are desired in the component 210. The polymer template 227 may be placed into a mold and encapsulated by injecting a ceramic slurry into the mold. During the injection of the ceramic slurry, the voids 228 may be infiltrated with ceramic slurry whereas the filled regions 229 may block the infiltration of the ceramic slurry. The polymer template 227 encapsulated in the ceramic slurry may then be fired at a low temperature to dry the ceramic slurry to produce a green body formed with ceramic walls 213 (see further details below).

The polymer template 227 may be formed from a low temperature thermoplastic material such as, but not limited to, high density polypropylene and high density polyethylene. Thermoplastics are desirable as template materials because they are easily machined, cut, drilled, or otherwise processed and finished to desired part specifications to provide complex structural features such as, for example, serpentine passages, cooling holes, and bolt holes, with little to no attending risks of structural fracture. In addition, the structure of the polymer template 227 may be easily formed by a manufacturing technique apparent to those of ordinary skill in the art such as, but not limited to, additive manufacturing, layer-wise deposition or three-dimensional printing, injection molding, compression molding, or resin transfer molding. Such techniques are all well-known and low-cost methods for providing polymeric materials having complex shapes and geometrical features.

In order to produce the desired ceramic component 210, the polymer template 227 is placed into a mold and injected with a ceramic slurry which infiltrates and encapsulates the polymer template 227 with a ceramic material such that the walls 213 form the desired surfaces and contours of the component 210 (e.g., the pressure side 217, the suction side, the leading edge 218, the trailing edge 219, the tip 220, the root 216, etc.). In addition, during infiltration with the ceramic slurry, the polymer template 227 becomes embedded in the ceramic material and the ceramic material forms any complex internal features present in the design of the component 210 (e.g., the internal passages 224, the turbulator strips 225, the cooling holes 226, cross-over holes, etc.). The polymer template 227 may be infiltrated with the ceramic material by injection molding, injection of the ceramic slurry, or by an infiltration technique apparent to those skilled in the art such as, but not limited to, vacuum pressure infiltration (VPI). The polymer template 227 embedded in the ceramic material may then be fired at low temperature to produce a green body 230, as shown in FIG. 4.

The green body 230 may then be sintered at an elevated temperature sufficient to solidify the ceramic material and volatilize any of the remaining polymeric materials of polymer template 227 not removed during the firing step to produce the green body 230, such that only the desired ceramic component 210 remains, as shown in FIG. 5. The resulting ceramic component 210 may be suitable for use as a component in high temperature regions of a gas turbine engine or other high temperature applications. Moreover, the resulting component 210 may exhibit any desired internal or external complex geometries (e.g., the root 216, the leading edge 218, the trailing edge 219, the internal passages 224, the turbulator strips 225, the cooling holes 226, etc.) due to the templating effect of the polymer template 227. Furthermore, the need for additional machining, drilling, cutting, or other potentially structurally threatening processing methods may be eliminated or at least substantially reduced. Also, given that the polymer template 227 may be completely removed during sintering, the method may eliminate the need for careful removal of the polymer template 227 from the ceramic component 210 and thereby reduce accompanying risks of component fracture.

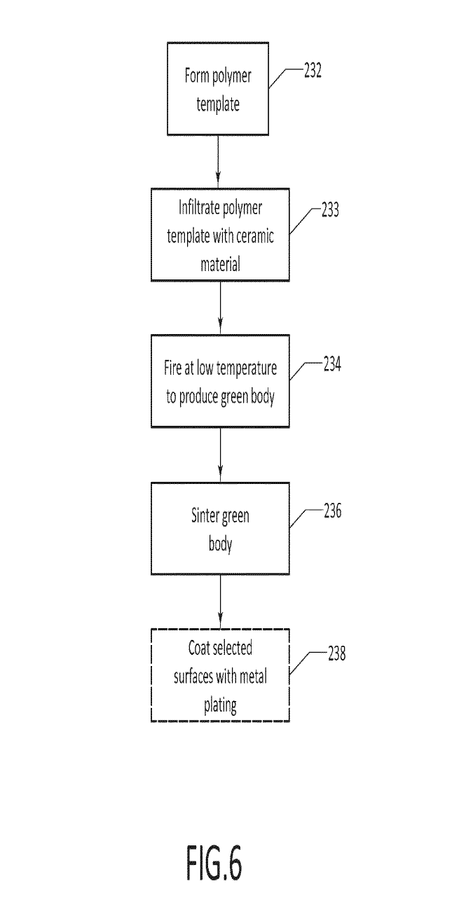

FIG. 6 schematically depicts a series of steps which may be performed to produce the ceramic component 210 using the polymer template 227. According to a first block 232, the polymer template 227 having a shape that is the inverse of the shape of the desired ceramic component 210 may be formed from a low temperature thermoplastic such as high density polypropylene or high density polyethylene using a polymer forming method such as, but not limited to, additive manufacturing, layer-wise deposition or three-dimensional printing, injection molding, compression molding, resin transfer molding, extrusion, or blow molding. According to a next block 233, the polymer template 227 may then be infiltrated or coated with the ceramic material by a technique such as, but not limited to, vacuum pressure infiltration, slurry casting, or coating. The polymer template 227 coated and infiltrated with the ceramic material may then be fired at a low temperature to produce a green body 230 (see FIG. 4) according to a next block 234, as shown. The green body 230 and polymer template 227 may then be sintered at an elevated temperature according to a block 236, as shown. During the block 236, the polymer template 227 may be completely volatilized and burned-off, leaving only the desired ceramic component 210 having the desired shape, including any complex geometrical features (see FIG. 5). Optionally, the ceramic component 210 may then be coated with one or more metal platings on one or more on selected external surfaces of the component 210 according to an optional block 238, as shown. If desired, masking of external surfaces of the component 210 may be performed during the block 238 to prevent metal layer deposition on non-selected external surfaces, as will be understood by those skilled in the art.

### INDUSTRIAL APPLICABILITY

From the foregoing, it can therefore be seen that the present disclosure can find industrial applicability in many situations including, but not limited to, situations requiring high strength, lightweight, and high temperature performance materials. The technology as disclosed herein may allow the fabrication of high strength and high temperature-resistant ceramic components with complex geometrical features using readily-molded polymer templates that may be burned off during a sintering step. In this way, complex geometrical features, such as serpentine passages, cooling holes, bolt holes, bosses, and hooks, may be installed in the ceramic component without the need for machining or drilling steps which could otherwise cause the ceramic material to fracture. The technology as disclosed herein may find wide industrial applicability in a wide range of areas such as, but not limited to, aerospace and automotive industries.

What is claimed is:

1. A method for fabricating a ceramic component, comprising:
forming a polymer template having a shape that is an inverse of a shape of the ceramic component;
placing the polymer template in a mold;
injecting the mold with a ceramic slurry;
firing the ceramic slurry at a temperature to produce a green body; and
sintering the green body at an elevated temperature to provide the ceramic component.

2. The method of claim 1, wherein the polymer template comprises voids that are devoid of polymeric material where walls are desired in the ceramic component, and filled regions that are filled with the polymeric material where open spaces are desired in the ceramic component.

3. The method of claim 2, wherein sintering the green body at an elevated temperature comprises volatilizing the polymer template.

4. The method of claim 2, further comprising coating a surface of the ceramic component with a metal plating.

5. The method of claim 2, wherein injecting the mold with the ceramic slurry comprises infiltrating the voids with the ceramic slurry.

6. The method of claim 2, wherein injecting the mold with the ceramic slurry comprises encapsulating the polymer template in the ceramic slurry.

7. The method of claim 2, wherein injecting the mold with the ceramic slurry comprises:
infiltrating the voids with the ceramic slurry; and
encapsulating the polymer template in the ceramic slurry.

8. The method of claim 7, wherein the polymer template is formed from a thermoplastic material selected from the group consisting of high density polypropylene and high density polyethylene.

9. The method of claim 8, wherein forming the polymer template comprises forming the polymer template by a method selected from the group consisting of additive manufacturing, layer-wise deposition, three-dimensional printing, injection molding, compression molding, resin transfer molding, extrusion, and blow molding.

10. The method of claim 8, wherein injecting the mold with the ceramic slurry comprises a method selected from the group consisting of injection, injection molding, and vacuum pressure infiltration.

11. A ceramic component formed by a method comprising:
forming a polymer template having voids that are devoid of polymeric material where walls are desired in the ceramic component, and filled regions that are filled with polymeric material where open spaces are desired in the ceramic component;
placing the polymer template in a mold;
injecting the mold with a ceramic slurry;
firing the ceramic slurry at a temperature to produce a green body; and
sintering the green body at an elevated temperature to provide the ceramic component.

12. The ceramic component of claim 11, wherein sintering the green body at an elevated temperature comprises volatilizing the polymer template.

13. The ceramic component of claim 12, further comprising coating a surface of the ceramic component with a metal plating.

14. The ceramic component of claim 12, wherein injecting the mold with the ceramic slurry comprises:
infiltrating the voids with the ceramic slurry; and
encapsulating the polymer template in the ceramic slurry.

15. The ceramic component of claim 14, wherein the ceramic component is a turbine blade for a gas turbine engine comprising an airfoil, a root, a leading edge, a trailing edge, and at least one internal passage extending inside of the airfoil.

16. A ceramic component having an external wall and at least one internal passage extending inside of the external wall, the ceramic component being formed by a method comprising:
forming a polymer template having voids that are devoid of polymeric material where the external wall is desired in the ceramic component, and filled regions that are filled with the polymeric material where the at least one internal passage is desired in the ceramic component;
placing the polymer template in a mold;
injecting the mold with a ceramic slurry;
firing the ceramic slurry at a temperature to produce a green body; and
sintering the green body at an elevated temperature to provide the ceramic component.

17. The ceramic component of claim 16, wherein sintering the green body at an elevated temperature comprises volatilizing the polymer template.

18. The ceramic component of claim 17, wherein injecting the mold with the ceramic slurry comprises:
infiltrating the voids with the ceramic slurry; and
encapsulating the polymer template with the ceramic slurry.

19. The ceramic component of claim 18, wherein the ceramic component comprises a turbine blade for a gas turbine engine, wherein the external wall defines an airfoil and a root of the airfoil, and wherein the at least one internal passage provides a passage for cooling air inside of the turbine blade.

20. The ceramic component of claim 18, wherein the ceramic component is a blade outer air seal for a gas turbine engine.
